(19) United States
(12) Patent Application Publication
(10) Pub. No.: US 2015/0292511 A1
(43) Pub. Date: Oct. 15, 2015

(54) HIGH VOLTAGE ELECTRIC DEVICE AND ELECTRIC COMPRESSOR

(71) Applicant: DENSO CORPORATION, Kariya-city, Aich-pref. (JP)

(72) Inventor: Koji Sakai, Kariya-city (JP)

(21) Appl. No.: 14/442,038

(22) PCT Filed: Oct. 8, 2013
(86) PCT No.: PCT/JP2013/005968

§ 371 Date: May 11, 2015

(30) Foreign Application Priority Data
Nov. 12, 2012 (JP) 2012-248243

(51) Int. Cl. F04D 25/06; H05K 7/20

(52) U.S. Cl. CPC F04D 25/06; H05K 7/20254; H05K 7/20263

(57) ABSTRACT

A high voltage electric device attached to a cooling unit includes heating components, an electric circuit board, a case, and an insulating member. The heating components are used at high voltage and are different in size. The heating components are fixed via lead wires respectively to the electric circuit board. The case accommodates the heating components and the electric circuit board. The insulating member seals the heating components and the electric circuit board in the case. An outermost peripheral surface of the insulating member on the cooling unit-side cooled by refrigerant is referred to as a reference surface. Respective shortest distances from the reference surface to the heating components are the same as each other. An electric compressor includes the high voltage electric device, an electric motor that is operated by electric power supplied by the high voltage electric device, and a compression mechanism that is driven by the electric motor and is applied to a refrigeration cycle. The cooling unit is cooled by the refrigerant drawn into the compression mechanism.

### CROSS REFERENCE TO RELATED APPLICATION

This application is based on Japanese Patent Application No. 2012-248243 filed on Nov. 12, 2012, the disclosure of which is incorporated herein by reference.

### TECHNICAL FIELD

The present disclosure relates to a high voltage electric device and an electric compressor.

### BACKGROUND ART

In Patent Document 1, for example, there is conventionally proposed an inverter device including a smoothing capacitor provided on a power substrate. Specifically, the inverter device has such a configuration that: the power substrate is disposed in a box-shaped module case, and the module case is filled up with a resin mold layer from the power substrate to a position to cover at least the smoothing capacitor. Accordingly, the smoothing capacitor is fixed by the resin mold layer, so that vibration resistance of the smoothing capacitor improves.

Prior Art Document

Patent Document

Patent Document 1: JP2010-74935A

However, according to the above-described conventional technique, the smoothing capacitor which is a heating component is disposed at a central part of the resin mold layer. Thus, the technique has a problem with cooling performance of the smoothing capacitor. As a result, the device may be reduced in size to improve the cooling performance of the smoothing capacitor. Particularly, a configuration including heating components different in size as well as the smoothing capacitor makes the device grow further in size. Therefore, the device needs to be further downsized to improve the cooling performance.

### SUMMARY OF INVENTION

The present disclosure addresses the above issues. Thus, it is an objective of the present disclosure to provide a high voltage electric device and an electric compressor that can realize downsizing of a configuration including heating components different in size.

To achieve the above objective of the present disclosure, in a first aspect of the present disclosure, a high voltage electric device includes a plurality of heating components, an electric circuit board, a case, and an insulating member. The plurality of heating components are used at high voltage and are different in size. The plurality of heating components are fixed via lead wires respectively to the electric circuit board. The case accommodates the plurality of heating components and the electric circuit board. The insulating member seals the plurality of heating components and the electric circuit board in the case.

An outermost peripheral surface of the insulating member on the cooling unit-side cooled by refrigerant is referred to as a reference surface. Respective shortest distances from the reference surface to the plurality of heating components are the same as each other.

Accordingly, since the heating components different in size are sealed with the insulating member, flexibility in layout of the heating components can be improved with the insulation of the heating components ensured. As a result, the heating components can be arranged at a constant distance from the reference surface which is a position having a higher cooling effect, so that cooling performance of the heating components is improved. Thus, the heating components can be reduced in size, and eventually the high voltage electric device can be downsized.

Moreover, an insulation distance of the heating components and the insulation distance between the heating components and the electric circuit board are reduced, so that the high voltage electric device can be downsized.

In a second aspect of the present disclosure, the insulating member includes a heat release insulating plate that is on an opposite side of the plurality of heating components from the electric circuit board and that is in contact with the plurality of heating components.

Accordingly, radiation performance of the heating components can be improved by the heat release insulating plate. As a result, the heating components can be reduced further in size, and eventually the high voltage electric device can be downsized.

### BRIEF DESCRIPTION OF DRAWINGS

The above and other objects, features and advantages of the present disclosure will become more apparent from the following detailed description made with reference to the accompanying drawings. In the drawings:

FIG. 1 is a circuit diagram illustrating the entire system in accordance with a first embodiment;

FIG. 2 is a sectional view illustrating an electric compressor with which an inverter device is integrated according to the first embodiment;

FIG. 3 is a sectional view illustrating the inverter device of the first embodiment;

FIG. 4 is a sectional view illustrating an inverter device and a cooling unit in accordance with a second embodiment;

FIG. 5 is a sectional view illustrating an inverter device and a cooling unit in accordance with a third embodiment;

FIG. 6 is a sectional view illustrating an inverter device and a cooling unit in accordance with a fourth embodiment;

FIG. 7 is a sectional view illustrating an inverter device and a cooling unit in accordance with a fifth embodiment; and

FIG. 8 is a sectional view illustrating an inverter device and a cooling unit in accordance with a sixth embodiment.

### EMBODIMENTS FOR CARRYING OUT INVENTION

Embodiments of the present disclosure will be described below in reference to the drawings. For the same or equivalent component in the following embodiments, its corresponding reference numeral is used in the drawings.

### First Embodiment

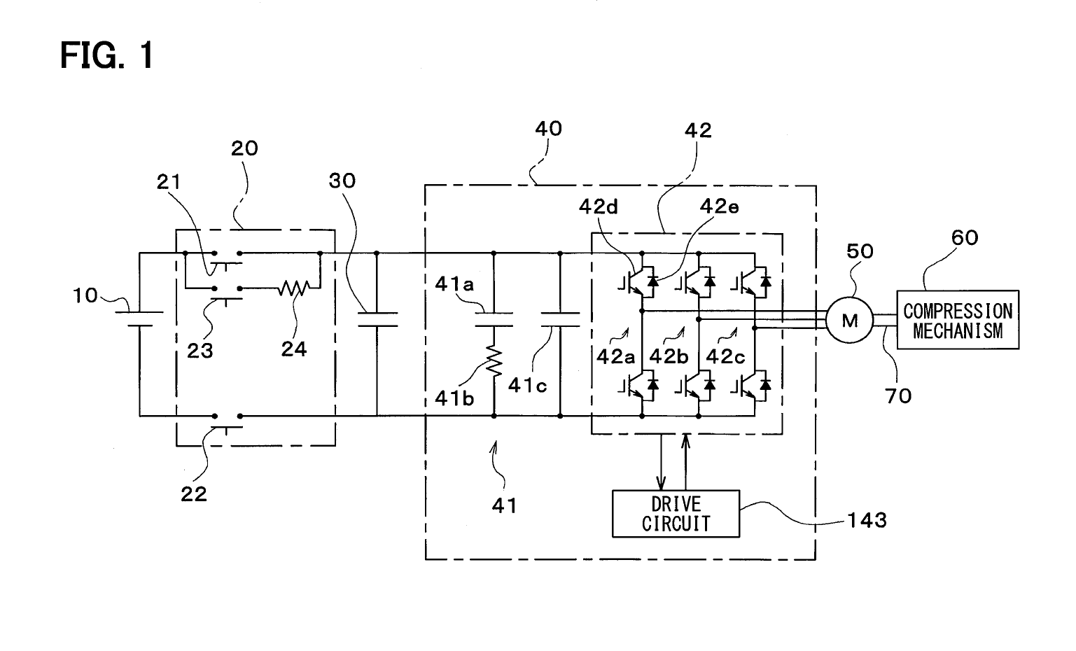

A first embodiment will be described below with reference to FIGS. 1 to 3. As illustrated in FIG. 1, a system having an electric compressor of the present embodiment includes a high-voltage battery 10, a high-voltage relay system 20, a smoothing capacitor 30, an inverter device 40, an electric motor 50, a compression mechanism 60, and a connecting mechanism 70.

The high-voltage battery 10 is a direct current power supply for driving the inverter device 40. The high-voltage relay system 20 has a function of preventing an inrush current from flowing through the inverter device 40 when applying a high voltage to the inverter device 40. Thus, the high-voltage relay system 20 includes a switch 21 connected to a positive electrode of the high-voltage battery 10, and a switch 22 connected to a negative electrode of the high-voltage battery 10. The high-voltage relay system 20 includes a switch 23 and a resistance 24. A series connection of the switch 23 and the resistance 24 is connected to the switch 21 in parallel therewith. For example, if an abnormal condition of the system is detected by an electrical control unit (ECU) which is not shown, the switches 21 to 23 are disconnected by the ECU.

The smoothing capacitor 30 is a capacitor that is charged with electricity in a high-voltage range of the voltage applied by the high-voltage battery 10 and that discharges electricity in a low-voltage range of the voltage applied by the high-voltage battery 10. Accordingly, the smoothing capacitor 30 serves to smooth a voltage applied to the inverter device 40.

The inverter device 40 is a high voltage electric device for converting the direct current voltage of the high-voltage battery 10 into an alternating-current voltage. The inverter device 40 includes a filter circuit 41, a switching circuit 42, and a drive circuit 143.

The filter circuit 41 serves to absorb noise because of operation of the switching circuit 42. The filter circuit 41 is configured to include a series connection of a capacitor 41a and a resistance 41b, and a capacitor 41c connected to this series connection in parallel therewith. The capacitor 41a absorbs the noise having slightly lower frequency characteristics than the capacitor 41c. The capacitor 41c absorbs the noise of higher frequency than the capacitor 41a.

For example, a film capacitor is used for the capacitor 41a. For example, an aluminum electrolytic capacitor is used as the capacitor 41c. When its temperature becomes high, the film capacitor tends to arouse concern over reduction in insulation resistance, change of capacitance, and change of dielectric loss tangent. When its temperature is low, the aluminum electrolytic capacitor tends to arouse concern over large equivalent series resistance (ESR) to reduce frequency characteristics and voltage change by the ESR. The aluminum electrolytic capacitor has larger internal resistance than the film capacitor. There is generally a single-digit difference in internal resistance between the aluminum electrolytic capacitor and the film capacitor.

Accordingly, the resistance 41b is series-connected to the capacitor 41a as a film capacitor. So that R1₊R2 which is a sum of a resistance value R1 of the internal resistance of the capacitor 41a and a resistance value R2 of the resistance 41b accords with a resistance value R3 of the internal resistance of the capacitor 41c at normal temperature, the resistance values are set. As a result, adjustment is made such that frequency characteristics of the series connection of the capacitor 41a and the resistance 41b generally equal frequency characteristics of the capacitor 41c. When the capacitance of the capacitor 41a as a film capacitor is set generally at a capacitance that is necessary mainly at low temperature, good frequency characteristics are obtained as the entire filter circuit 41.

The switching circuit 42 is a circuit that generates three-phase (U-phase, V-phase, W-phase) alternating voltage and current to drive the high-voltage electric motor 50. The switching circuit 42 includes a U-phase arm 42a, a V-phase arm 42b, and a W-phase arm 42c. These arms 42a to 42c are connected in parallel between a power source line and a ground line.

Each of the arms 42a to 42c is configured by serially-connected two switching elements 42d. A diode element 42e for passing an electric current from the emitter side to the collector side is connected between a collector and an emitter of each switching element 42d. Respective intermediate points of the arms 42a to 42c are connected to corresponding phase ends of phase-coils of the electric motor 50. Each switching element 42d is, for example, an insulated gate bipolar transistor (IGBT), and each diode element 42e is a free wheeling diode (FWD).

The drive circuit 143 is a circuit for operating each switching element 42d of the switching circuit 42. Accordingly, the drive circuit 143 controls the electric current passing through each phase of the electric motor 50 such that the electric motor 50 outputs a predetermined torque. The drive circuit 143 performs, for example, detection of the voltage and electric current necessary to drive the electric motor 50, output of a switching signal, and various control calculations.

The electric motor 50 is a motor for high voltage that is configured by commonly connecting the ends of three coils of U-phase, V-phase, and W-phase to the middle point. The other end of the U-phase coil of the electric motor 50 is connected to an intermediate point between the switching elements 42d of the U-phase arm 42a of the switching circuit 42. This applies equally to the V-phase coil and the W-phase coil. Accordingly, the electric motor 50 operates based on the three-phase power supplied by the inverter device 40.

The compression mechanism 60 is a mechanism that is driven by the electric motor 50 to compress refrigerant, for example. The compression mechanism 60 is applied, for example, to a refrigeration cycle. The connecting mechanism 70 is a connecting shaft that connects together the electric motor 50 and the compression mechanism 60, and is a “shaft”.

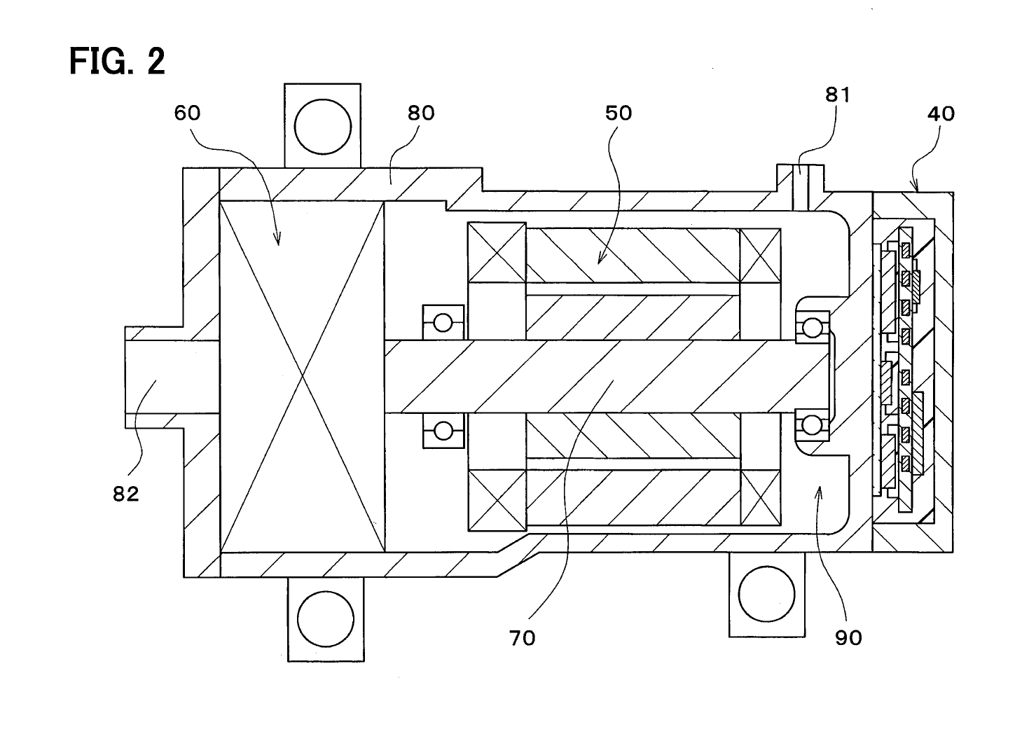

In the above-described system, the compression mechanism 60, the electric motor 50, and the inverter device 40 are integrated as illustrated in FIG. 2. The compression mechanism 60 and the electric motor 50 which are connected by the connecting mechanism 70 are accommodated in a cylindrical housing 80, and as a result, an electric compressor is configured.

The housing 80 includes a suction port 81 through which the refrigerant is drawn into the housing 80, and a discharge port 82 through which the refrigerant compressed through the electric motor 50 and the compression mechanism 60 is discharged to the outside of the housing 80. Inside the housing 80, the electric motor 50 transmits rotational driving force to the compression mechanism 60 through the connecting mechanism 70.

Accordingly, the compression mechanism 60 is operated to draw the refrigerant into the housing 80 through the suction port 81 and compress the drawn refrigerant, and to discharge the compressed refrigerant through the discharge port 82.

Because the refrigerant is drawn into the housing 80 through the suction port 81, the suction port 81-side of the electric compressor serves as a cooling unit 90 that is cooled by this refrigerant. Specifically, the temperature of the housing 80 near the suction port 81 is maintained at low temperature, and this part is referred to as the cooling unit 90. The inverter device 40 is fixed to an outer wall surface of the housing 80 that defines the cooling unit 90. In the present embodiment, the inverter device 40 is located on the central axis of the connecting mechanism 70.

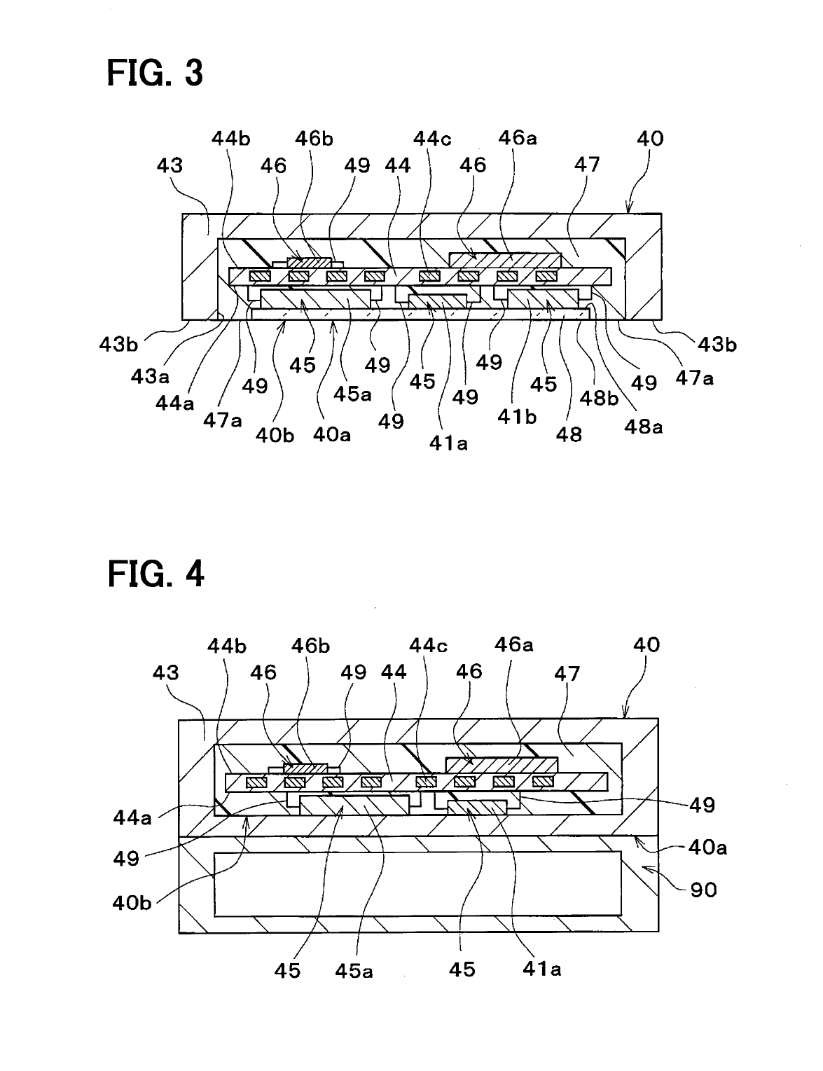

As illustrated in FIG. 3, the inverter device 40 is configured to include a case 43, an electric circuit board 44, heating components 45, electronic components 46, a mold resin 47, and a heat release insulating plate 48.

The case 43 is a container-shaped component accommodating the electric circuit board 44, the heating components 45, the electronic components 46, the mold resin 47, and the heat release insulating plate 48. In the present embodiment, the case 43 includes an opening part 43a through which to connect the inside and outside. Such a case 43 is formed through press-working and cutting of a metallic material such as die-casting ADC12. The metallic material such as die-casting ADC12 may be formed by casting work and cutting work, for example.

The electric circuit board 44 is a plate-shaped component including one surface 44a, and the other surface 44b on an opposite side of the electric circuit board 44 from this one surface 44a. The electric circuit board 44 includes internal components 44c that are incorporated into this electric circuit board 44. For example, a resistance element or a wire is used as the internal component 44c. For example, a glass epoxy board or a ceramic board is employed for the electric circuit board 44.

The heating components 45 are electronic components that are used at a high voltage and that generate a large amount of heat. Each heating component 45 is electrically-connected and fixed to a wire (not shown) which is formed on the one surface 44a of the electric circuit board 44, via lead wires 49.

The heating components 45 are a semiconductor power device 45a, capacitors 41a, 41c for filtering, and a resistance 41b that is serially-connected to the capacitor 41a. The capacitor 41 c is omitted in FIG. 3.

The semiconductor power device 45a is obtained by molding in resin a semiconductor chip in which the switching circuit 42 is formed. The capacitors 41a, 41c are a ceramic capacitor and the above-described film capacitor, for example. The resistance 41b is configured as a discrete part. As described above, the heating components 45 are electronic components that are different in type and size respectively.

The electronic components 46 are components that are packaged on the other surface 44b of the electric circuit board 44. A component 46a that is obtained by molding in resin a semiconductor chip in which the drive circuit 143 is formed, and a surface-mounted component 46b are employed for the electronic components 46. In the present embodiment, this component 46b is electrically-connected and fixed to a wire (not shown) formed on the other surface 44b of the electric circuit board 44 via the lead wires 49.

The mold resin 47 is a sealing member that seals the heating components 45, the electronic components 46, the electric circuit board 44, and the heat release insulating plate 48 inside the case 43. The mold resin 47 is formed from, for example, epoxy resin. “Sealing” includes meaning of not only complete enclosure such as the heating components 45 but also partial fixation such as the heat release insulating plate 48.

The heat release insulating plate 48 is a heat release plate for discharging heat of the heating components 45 to the outside. The heat release insulating plate 48 is located on an opposite side of the heating components 45 from the electric circuit board 44, and is in contact with the heating components 45. The heat release insulating plate 48 is sealed with the mold resin 47 such that an opposite surface 48b on its opposite side from a contact surface 48a, with which the heating components 45 are in contact, is exposed from the mold resin 47. The heat release insulating plate 48 is formed from ceramics such as aluminium nitride or alumina so that it can deliver heat release performance and insulation performance.

A method for making the inverter device 40 includes the following processes. Firstly, the heating components 45 and the electronic components 46 are packaged on the electric circuit board 44, and they are arranged in the case 43 together with the heat release insulating plate 48. Then, this case 43 is disposed in a metal mold (not shown) and the mold resin 47 is poured into the metal mold. Accordingly, the electric circuit board 44, the heating components 45, the electronic components 46, and the heat release insulating plate 48 are sealed in the case 43. As a result, the inverter device 40 is completed. The inverter device 40 is, for example, screwed to the housing 80 by a flange part (not shown) provided for the case 43. This is the entire configuration of the system including the electric compressor of the present embodiment.

In the above-described configuration of the inverter device 40, an open end surface 43b of the case 43, an exposed surface 47a of the mold resin 47 that is exposed from the case 43 and the heat release insulating plate 48, and the opposite surface 48b of the heat release insulating plate 48 are located on the same plane. This plane is a plane where parts of the case 43, the mold resin 47, and the heat release insulating plate 48 are in direct contact with the cooling unit 90, and is a plane that is cooled by the cooling unit 90. With this plane referred to as a cooling surface 40a, the cooling surface 40a of the inverter device 40 is in contact with the housing 80 of the cooling unit 90. Accordingly, heat of each of the heating components 45 is transmitted to the cooling unit 90 through the heat release insulating plate 48 and the cooling surface 40a.

With an outermost peripheral surface of the mold resin 47 and the heat release insulating plate 48 on the cooling unit 90-side cooled by the refrigerant referred to as a reference surface 40b, the shortest distances of the heating components 45 from the reference surface 40b coincide with each other. Since the heating components 45 are different in shape as described above, when the heat release insulating plate 48-side positions of the heating components 45 are aligned, the widths of clearances between the heating components 45 and the electric circuit board 44 are different from each other as illustrated in FIG. 3. However, because of the mold resin 47 entering into these clearances, insulation is maintained between the heating components 45 and the electric circuit board 44. When the reference surface 40b is defined as described above, in the present embodiment, the cooling surface 40a and the reference surface 40b are the same surface.

Effects of the above-described arrangement of the heating components 45 in the inverter device 40 will be explained. Because the heating components 45 are arranged on the cooling unit 90-side, performance in cooling the heating components 45 improves. Particularly, the heating components 45 are arranged at a constant distance from the reference surface 40b which is a position where the cooling effect is further enhanced, and thus the performance in cooling the heating components 45 improves. Accordingly, each heating component 45 itself can be reduced in size, and eventually the inverter device 40 can be downsized.

The heating components 45 and the electric circuit board 44 are sealed with the mold resin 47. Consequently, an insulation distance between the heating components 45, and insulation distances between the heating components 45 and the electric circuit board 44 can be reduced. Thus, a spatial distance between the components can be significantly reduced. As a result, the inverter device 40 can be downsized.

The heating components 45 which are different in size are sealed with the mold resin 47. Accordingly, greater flexibility in layout of the heating components 45 is achieved with the insulation of the heating components 45 ensured. Hence, even though the heating components 45 are arranged with the cooling surface 40a serving as a reference in view of the performance in cooling the heating components 45, the inverter device 40 can be designed to be sufficiency downsized.

Furthermore, in the present embodiment, the inverter device 40 includes the heat release insulating plate 48. The performance in cooling the heating components 45 can be further improved by this heat release insulating plate 48. Therefore, the heating components 45 can be reduced further in size, and eventually the high voltage electric device can be downsized.

In addition, the mold resin 47 and the heat release insulating plate 48 of the present embodiment may correspond to an “insulating member”.

### Second Embodiment

In the present embodiment, a part of the present disclosure that is different from the first embodiment will be described. In the present embodiment, as illustrated in FIG. 4, a case 43 is configured as a container having a hollow shape. The case 43 accommodates in its hollow portion an electric circuit board 44, heating components 45, electronic components 46, and a mold resin 47. In the present embodiment, an inverter device 40 is not provided with the heat release insulating plate 48. The resistance 41 b is omitted in FIG. 4.

The mold resin 47 seals the electric circuit board 44, the heating components 45, and the electronic components 46, and is also provided between the heating components 45 and the case 43 inside the case 43. As a consequence, the insulation between the heating components 45 and the case 43 is ensured. Grease and resin may be provided between the heating components 45 and the case 43 to ensure this insulation.

The case 43 is fixed to a cooling unit 90 such that the heating components 45 in the case 43 are located on the cooling unit 90-side. Accordingly, an outer wall surface of the case 43 that is in direct contact with the cooling unit 90 serves as a cooling surface 40a which is cooled by the cooling unit 90. The cooling unit 90 is not limited to the electric compressor of the first embodiment. The cooling unit 90 may be anything as long as it can cool the cooling surface 40a by, for example, water cooling or air cooling.

In the present embodiment, an outermost peripheral surface of the mold resin 47 on the cooling unit 90-side serves as a reference surface 40b. The shortest distances of the heating components 45 from the reference surface 40b are the same as each other.

As described above, as a result of the configuration of covering the entire mold resin 47 in the case 43, the inverter device 40 which is excellent in exchangeability/interchangeability with the conventional structure can be obtained. Additionally, since the inverter device 40 does not include the heat release insulating plate 48, the inverter device 40 can be downsized by reduction in the number of components. The mold resin 47 of the present embodiment may correspond to the “insulating member”.

### Third Embodiment

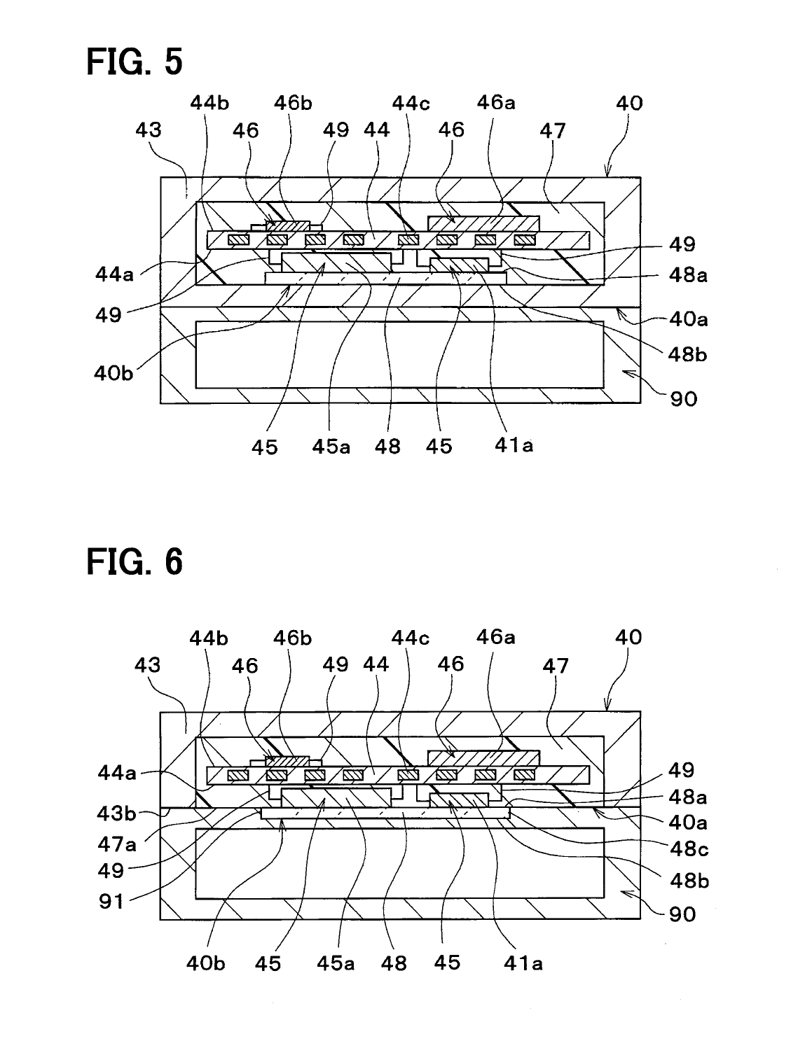

In the present embodiment, a part of the present disclosure that is different from the second embodiment will be described. As illustrated in FIG. 5, a heat release insulating plate 48 is provided between an inner wall surface of a case 43 and heating components 45. Accordingly, the performance in cooling the heating components 45 can be improved.

When an outermost peripheral surface of a mold resin 47 and the heat release insulating plate 48 on a cooling unit 90-side is referred to as a reference surface 40b, in the present embodiment, the reference surface 40b is the same surface as an opposite surface 48b of the heat release insulating plate 48. The heating components 45 are respectively in contact with a contact surface 48a of the heat release insulating plate 48. Thus, the shortest distances of the heating components 45 from the reference surface 40b accord with each other.

In addition, the mold resin 47 and the heat release insulating plate 48 of the present embodiment may correspond to the “insulating member”.

### Fourth Embodiment

In the present embodiment, a part of the present disclosure that is different from the first embodiment will be described. As illustrated in FIG. 6, a heat release insulating plate 48 is disposed on an exposed surface 47a of a mold resin 47. Accordingly, the heat release insulating plate 48 projects from an open end surface 43b of a case 43 and the exposed surface 47a of the mold resin 47.

A cooling surface 40a includes the open end surface 43b of the case 43, the exposed surface 47a of the mold resin 47 that is exposed from the case 43 and the heat release insulating plate 48, and an opposite surface 48b and a side surface 48c of the heat release insulating plate 48. Consequently, the cooling surface 40a is not a single flat surface but is a surface including a level difference of the heat release insulating plate 48.

Similar to the first embodiment, a reference surface 40b is an outermost peripheral surface of the mold resin 47 and the heat release insulating plate 48 on a cooling unit 90-side. Specifically, in the present embodiment, the reference surface 40b includes the exposed surface 47a of the mold resin 47, the opposite surface 48b and the side surface 48c of the heat release insulating plate 48, and is a surface including a level difference of the heat release insulating plate 48 similar to the cooling surface 40a. As a result, the cooling surface 40a and the reference surface 40b are the same surface.

On the other hand, a cooling unit 90 includes a recessed part 91 on its surface on which an inverter device 40 is disposed. The recessed part 91 is a part where the heat release insulating plate 48 of the inverter device 40 is disposed. The recessed part 91 is formed to have the same size as the heat release insulating plate 48.

As described above, the heat release insulating plate 48 projects from the exposed surface 47a of the mold resin 47, and the case 43 is sealed with the mold resin 47. Accordingly, the case 43 of the inverter device 40 can be made smaller by a thickness of the heat release insulating plate 48. When the inverter device 40 is attached to the cooling unit 90, the heat release insulating plate 48 is accommodated in the recessed part 91 of the cooling unit 90. As a consequence, the inverter device 40 can be downsized by a thickness of the heat release insulating plate 48.

### Fifth Embodiment

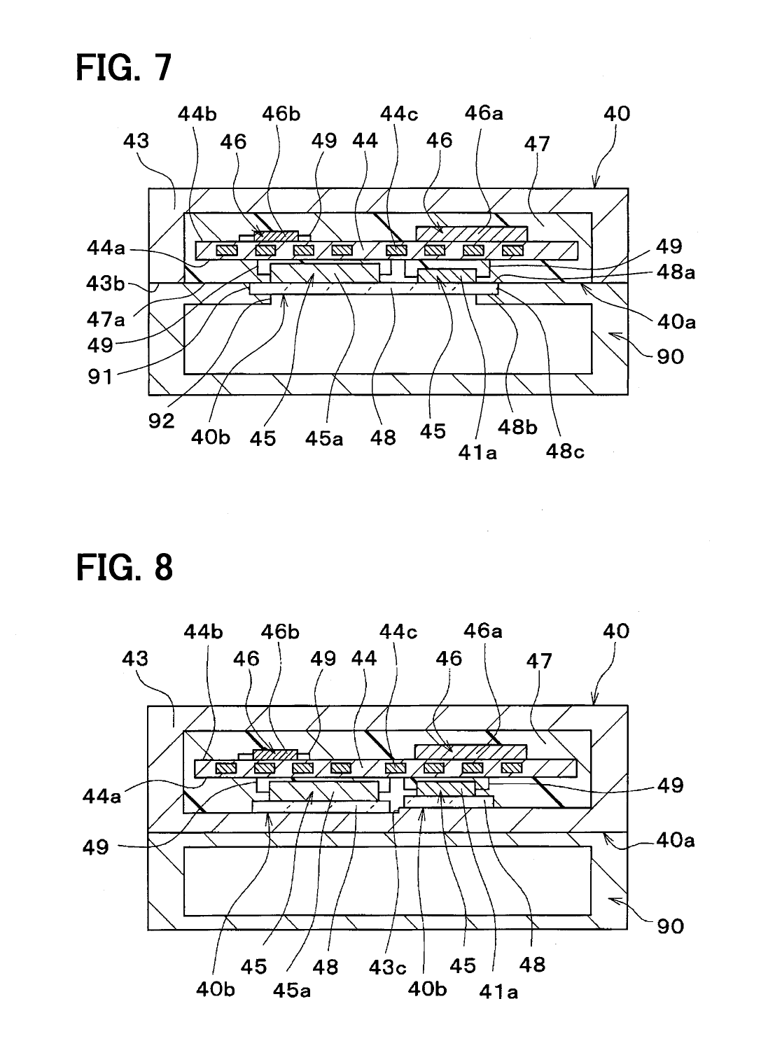

In the present embodiment, a part of the present disclosure that is different from the fourth embodiment will be described. In the present embodiment, as illustrated in FIG. 7, a through hole 92 connecting the inside and outside of a cooling unit 90 is formed at a recessed part 91 of the cooling unit 90. Accordingly, a cooling surface 40a of an inverter device 40 is in direct contact with the refrigerant in the cooling unit 90 so as to be cooled by the refrigerant.

As a result, the performance in cooling heating components 45 is further improved, so that the heating components 45 can be made even smaller.

In consideration of strength of a heat release insulating plate 48, the inverter device 40 may be disposed at a position of the cooling unit 90 that does not receive force of the refrigerant or at a position of the cooling unit 90 where this force is relatively small.

### Sixth Embodiment

In the present embodiment, a part of the present disclosure that is different from the third embodiment will be described. As illustrated in FIG. 8, a level difference 43c is provided at a part of an inner wall surface of a case 43 of an inverter device 40 on which heat release insulating plates 48 are arranged.

The heat release insulating plates 48 are arranged separately respectively on an upper level and on a lower level of the level difference 43c. Thicknesses of the two heat release insulating plates 48 are the same.

In the case of such a configuration, a reference surface 40b which is an outermost peripheral surface of a mold resin 47 and the heat release insulating plates 48 on a cooling unit 90-side is a surface that is in accordance with the level difference 43c of the case 43. Consequently, the reference surface 40b is not a single flat surface but is a surface including a level difference of the case 43. Even though the reference surface 40b is defined as above, a distance from the reference surface 40b to a capacitor 41 a on the upper level of the level difference 43c of the case 43, and a distance from the reference surface 40b to a semiconductor power device 45a on the lower level of the level difference 43c of the case 43 are the same.

Because the level difference 43c is provided on the inner wall surface of the case 43 as described above, greater flexibility in arrangement of heating components 45 is achieved. As a result, the inverter device 40 can be downsized. In the present embodiment, a cooling surface 40a is a surface of the case 43 that is in contact with the cooling unit 90, and is not the same surface as the reference surface 40b.

Modifications to the above-described embodiments will be described below. The configuration of the electric compressor and the inverter device 40 illustrated in the above embodiments is an example, and another configuration that can realize the present disclosure is employable for the electric compressor and the inverter device 40 without their limitation to the above-described configuration. For example, the configuration of the electric compressor illustrated in FIG. 2 is an example, and another configuration may be employed for the electric compressor.

In the above embodiments, the mold resin 47 is embedded between the electric circuit board 44 and the heating components 45. Alternatively, the heating components 45 may be surface-mounted on the one surface 44a of the electric circuit board 44.

In addition, the above embodiments may be combined together appropriately. For example, the cooling unit 90 including the through hole 92 illustrated in the fifth embodiment can be applied to the inverter device 40 except in the fifth embodiment.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A high voltage electric device adapted to be attached to a cooling unit, the high voltage electric device comprising:
a plurality of heating components that are used at high voltage and are different in size;
an electric circuit board to which the plurality of heating components are fixed via lead wires respectively;
a case that accommodates the plurality of heating components and the electric circuit board; and
an insulating member that seals the plurality of heating components and the electric circuit board in the case, wherein:
an outermost peripheral surface of the insulating member on the cooling unit side cooled by refrigerant is referred to as a reference surface; and
respective shortest distances from the reference surface to the plurality of heating components are the same as each other.

2. The high voltage electric device according to claim 1, wherein the insulating member includes a heat release insulating plate that is on an opposite side of the plurality of heating components from the electric circuit board and that is in contact with the plurality of heating components.

3. The high voltage electric device according to claim 1, wherein: surfaces of the case and the insulating member that are in contact with the cooling unit. and that are cooled by the cooling unit are referred to as a cooling surface; and
the cooling surface is in direct contact with the refrigerant in the cooling unit so as to be cooled.

4. The high voltage electric device according to claim 1 wherein the plurality of heating components are a semiconductor power device, a capacitor for filtering, and a resistance that is serially-connected to the capacitor.

5. The high voltage electric device according to claim 1, wherein the cooling unit is cooled by the refrigerant drawn into a compression mechanism which is applied to a refrigeration cycle.

6. An electric compressor comprising:
the high voltage electric device recited in claim 1;
an electric motor that is operated by electric power supplied by the high voltage electric device and
a compression mechanism that is driven by the electric motor and is applied to a refrigeration cycle, wherein the cooling unit is cooled by the refrigerant drawn into the compression mechanism.
